(19) United States
(12) Patent Application Publication
(10) Pub. No.: US 2010/0024717 A1
(43) Pub. Date: Feb. 4, 2010

(54) Reversed action diameter control in a semiconductor crystal growth system

(76) Inventors: Benno Orschel, Salem, OR (US); Manabu Nishimoto, Saga-shi (JP)

Correspondence Address: BRINKS HOFER GILSON & LIONE, P.O. BOX 10395, CHICAGO, IL, 60610, US

(21) Appl. No.: 12/221,224

(22) Filed: Jul. 31, 2008

(51) Int. Cl. C30B 15/22; C30B 35/00

(52) U.S. Cl. 117/15; 117/202

(57) ABSTRACT

A semiconductor crystal growth method includes pulling a crystal from melt in a crucible at a nominal pull speed and generating a crucible lift signal to compensate reduction in melt level in the crucible. Based on diameter of the crystal, the method includes generating a correction signal and combining the crucible lift signal and the correction signal to keep the crystal diameter substantially constant.

### BACKGROUND

The present invention relates generally to growth of semiconductor crystals. More particularly, the present invention relates to a reversed action diameter control in a semiconductor crystal growth system.

Most processes for fabricating semiconductor electronic components are based on single crystal silicon. Conventionally, the Czochralski process is implemented by a crystal pulling machine to produce an ingot of single crystal silicon. The Czochralski or CZ process involves melting highly pure silicon or polycrystalline silicon in a crucible located in a specifically designed furnace. The crucible is typically made of quartz or other suitable material. After the silicon in the crucible is melted, a crystal lifting mechanism lowers a seed crystal into contact with the silicon melt. The mechanism then withdraws the seed to pull a growing crystal from the silicon melt. The crystal is substantially free of defects and therefore suitable for manufacture modern semiconductor devices such as integrated circuits. While silicon is the exemplary material in this discussion, other semiconductors such as gallium arsenide, indium phosphide, etc. may be processed in similar manner, making allowances for particular features of each material.

A key manufacturing parameter is the diameter of the ingot pulled from the melt. After formation of a crystal neck or narrow-diameter portion, the conventional CZ process enlarges the diameter of the growing crystal. This is done under automatic process control by decreasing the pulling rate or the temperature of the melt in order to maintain a desired diameter. The position of the crucible is adjusted to keep the melt level constant relative to the crystal. By controlling the pull rate, the melt temperature, and the decreasing melt level, the main body of the crystal ingot grows with an approximately constant diameter. During the growth process, the crucible rotates the melt in one direction and the crystal lifting mechanism rotates its pulling cable or shaft along with the seed and the crystal in an opposite direction.

In conventional CZ control methods, a diameter control system monitors crystal diameter and produces a corrective term λ(Δd,t) as a function of diameter deviations. The diameter control operation adds this correction to the nominal crystal-pull-speed while the crucible lift rate is slaved to crystal-pull-speed. This is done in order to compensate the dropping crucible melt-level, so that the melt position remains substantially constant. The melt position may change slowly during the course of the process.

The area of the melt below the crystal which is raised above the melt level is called the meniscus. Diameter deviations are caused by meniscus height deviations. Meniscus height deviations are the result of temperature gradient changes in the melt, due to buoyancy in the melt. Buoyancy occurs in the melt due to naturally occurring regions of melt that are hotter than other regions, and therefore rise, or regions that are colder and therefore sink. If the melt temperature gradient becomes smaller as a result of a buoyancy fluctuation, the crystallization rate increases, which in turn leads to a reduced meniscus height. The reduced meniscus height then causes the diameter of the crystal to become larger, which is detected by the diameter measurement system. The control system then produces a corrective term that increases crystal pulling speed, in order to keep the diameter constant.

Ideally, the diameter control system keeps the meniscus height at a constant value that results in cylindrical growth, so that the resulting pull speed variations reflect the buoyancy driven melt temperature gradient fluctuations. This assumption is not entirely valid with conventional diameter control systems because they suffer from significant control model and measurement errors.

One important control parameter is v/G, the ratio of the pull speed v to the temperature gradient G. Temperature gradients include G_{S} which is the temperature gradient in the solid or the crystal, and G_{L} which is the temperature gradient in the liquid or melt. A problem with conventional systems in terms of v/G is that, for instance, a temporary reduction of melt temperature gradient G_{L} will be detected when the diameter control system detects increasing diameter of the crystal. The diameter control system responds with an increased pull speed, v. As a result, the already increased v/G increases even further. This condition persists until the buoyancy fluctuation disappears.

Some crystal growth applications are directed to producing low defect silicon, or a silicon crystal with essentially no interstitial or vacancy defects. Applications such as low defect silicon growth are only concerned with v/G_{S} in the crystal. In such applications, G_{S} remains more or less constant during such fluctuations, so that the v/G_{S} deviation is only proportional to the pull-speed correction that is a result of the melt gradient deviation.

However, the case is worse with heavily doped CZ applications. In heavily doped silicon, dopant is added to alter the electrical properties of the silicon. With heavily doped silicon, constitutional super cooling can occur. Because of the segregation effect, in front of the solid liquid boundary, there is a small layer of melt with slightly higher dopand concentration than in the rest of the melt. Since the solidification temperature is a function of dopand concentration, spontaneous crystallization in that layer can occur as a result of a drop in melt temperature. This phenomenon is called constitutional super cooling and the likelihood for it to occur rises as the ratio v/G_{L} increases. Heavily doped silicon applications have to consider v/G_{L} in the melt because they have to avoid such constitutional super cooling. In this case, the v/G_{L} deviation has two contributions, the reduced G_{L} and the resulting increased V.

Yield and productivity of both low defect silicon and heavily doped silicon applications suffer greatly from the problem of v/G_{S} and v/G_{L} deviation respectively. This problem may be a roadblock for future applications such as larger diameter CZ crystal grown or increased doping and generally has a negative impact on yields.

Several attempts have been made to solve this problem, but with little success. Most attempts use substantial hardware and are cost intensive. Some proposals attack the problem at its source, which is the control system. The control system for a crystal growth system is usually of relatively low cost since it is usually implemented through control software without the need for extra hardware.

One common approach to solving this problem involves the application of magnetic fields in order to dampen the buoyancy fluctuations. However, this approach adds the high extra cost of magnets Another approach is the use of cooling jackets or a heat shield in order to increase temperature gradients.

Another example of solving the problem, this time at the control system level, proposes a fixed seed lift setup in which the crystal diameter is only controlled by heater power. This is achieved by using a complex heat balance model in order to optimize heater control and minimize diameter fluctuations. Nominally, this method results in constant v/G_{S} and reduced v/G_{L} deviations.

Unfortunately, constant v/G_{S} is not really achievable just by fixing the pull speed, because the interface growth rate still follows the G_{L} fluctuation. Due to lack of an immediate corrective action, this results in meniscus height deviations and consequently diameter deviations. Because of inherently large time constants, controlling the diameter only by heater power will cause significant diameter deviations, no matter how sophisticated the underlying control model may be.

These large diameter deviations however, reduce the yield and productivity that fixing the pull speed was intended to gain. In addition, these diameter deviations will also cause undesired interface shape changes and they will reduce run-to-run stoichiometric consistency.

Accordingly, there remains a need for an improved system and method for solving the problem of v/G_{L} deviation and improving the growth of semiconductor crystals.

### BRIEF SUMMARY

The system and method described herein apply diameter feed-back-control in a new way in order to reduce or eliminate v/G deviations in a crystal growth application.

The ratio v/G is one of the most important crystal growing parameters. In the case of low defect silicon, v/G_{S} determines whether or not low defect silicon is grown and in the case of heavily doped CZ v/G_{L} determines constitutional super-cooling conditions.

Conventional CZ control systems have been unable to simultaneously stabilize v/G while controlling diameter and crystal growth. In order to solve this important problem, the present embodiments provide a new diameter control method while at the same time reducing or eliminating v/G deviations.

Equation (1) is the one-dimensional heat balance equation, describing the crystallization rate v in dependence of the solid G_{S} and liquid G_{L} temperature gradients at the solid-liquid phase boundary. The parameters in equation (1) stand for the specific latent heat of the solid phase L, the solid phase heat conductivity k_{S} and the liquid phase heat conductivity k_{L}.

L_{S}v=k_{S}G_{S}−k_{L}G_{L} (1)

The situation is worst in the case of heavily doped CZ material, because the diameter control always increases v/G_{L} deviations that occur naturally as a result of buoyancy-induced G_{L} deviations. For instance, if, as a result of buoyancy, G_{L} drops, the crystallization rate v will increase, further increasing the v/G deviation. Both, the original drop of G_{L} and the resulting increase of v will cause an increase of v/G_{L}. This drives the system into a critical condition where constitutional super-cooling is more likely to occur.

If there were no diameter control (e.g., a constant pull speed), this condition would only exist temporarily until the meniscus height changed enough to increase G_{L} and decrease G_{S} enough to result in v being equal to the pull speed again. The result would be a slightly increased v/G_{L} and an outgrowing diameter.

However, the situation changes with the addition of a diameter control system. In order to prevent the diameter from growing out, the diameter control system will increase the pull rate to maintain meniscus height for cylindrical growth. As a result, the critical condition will exist for a prolonged length of time, significantly increasing chances for constitutional super-cooling and other related structure loss causing phenomena such as cellular growth.

The situation is similar in production of low defect silicon. Here, the value of v/G_{S} determines whether low defect silicon conditions exist or not. Deviations from the optimal v/G_{S} will drive the system into a vacancy or interstitial defect-rich growth condition. Here too, v/G_{S} deviations originate from buoyancy induced G_{L} deviations. Deviations that initially cause the diameter control reactions do not affect the v/G_{S} control objective. However, the diameter control also drives v/G_{S} away from favorable conditions.

### BRIEF DESCRIPTION OF THE DRAWINGS

FIG. 1 is a block diagram of an exemplary semiconductor crystal growth apparatus;

FIG. 2-FIG. 8 are a series of drawings illustrating heat balance in a semiconductor crystal growth apparatus;

FIG. 9 illustrates conventional prior art diameter control in a semiconductor crystal growth apparatus;

FIG. 10 illustrates a first embodiment of a diameter control in a semiconductor crystal growth apparatus; and

FIG. 11 illustrates a second embodiment of a diameter control in a semiconductor crystal growth apparatus

FIG. 12 illustrates a third embodiment of a diameter control in a semiconductor crystal growth apparatus.

### DETAILED DESCRIPTION OF THE DRAWINGS AND THE PRESENTLY PREFERRED EMBODIMENTS

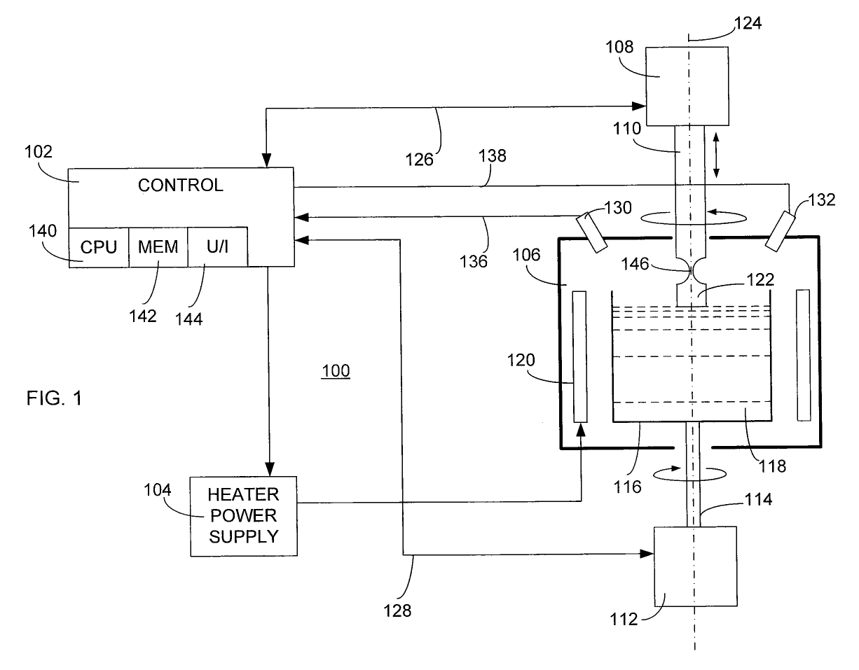

Referring now to the drawing, FIG. 1 is a block diagram of an exemplary semiconductor crystal growth apparatus 100. The apparatus 100 includes a control unit 102, a heater power supply 104 and a crystal growth chamber 106. The apparatus 100 further includes a crystal drive unit 108, a crystal shaft 110, a crucible drive unit 112 and a crucible drive shaft 114.

Contained within the chamber 106 is a crucible 116 containing melt 118 and a heater 120. In the illustration of FIG. 1, a semiconductor crystal 122 is formed from the melt 118. The control unit 102 is coupled with the heater power supply 104 to control the heater power supply 104. By controlling the heater power supply 104, the temperature of the melt 118 is controlled to permit controlled growth of the semiconductor crystal 122. To further control temperature of the melt, a heater controller may be added with the heater power supply 104 as well.

The crystal drive unit 108 operates to pull the crystal shaft 110 along the center axis 124. The crystal drive unit 108 also operates to rotate the crystal shaft 110 about the center axis 124. In FIG. 1, counterclockwise rotation is indicated, but clockwise rotation may be substituted and both may be available by appropriate control of the crystal drive unit 108. Rotation or movement of the crystal drive shaft 110 causes like rotation or movement of the crystal 122. The crystal drive unit 108 includes one or more electric motors or other devices for pulling and rotating the crystal shaft 110. The crystal drive unit 108 is controlled by signals proved over a control line 126 from the control unit 102.

Similarly, the crucible drive unit 112 operates to move the crucible drive shaft 114 along the center axis 124 and to rotate the crucible drive shaft 114 about the center axis 124. In FIG. 1, clockwise rotation is indicated, but counterclockwise rotation may be substituted and both may be available by appropriate control of the crucible drive unit 112. Rotation or movement of the crucible drive shaft 114 causes like rotation or movement of the crucible 116. The crucible drive unit 112 includes one or more electric motors or other devices for pulling and rotating the crucible drive shaft 114. The crucible drive unit 112 is controlled by signals proved over a control line 128 from the control unit 102.

The chamber 106 includes one or more sensors. In the exemplary embodiment of FIG. 1, these include a camera 130 and a temperature sensor 132. The camera 130 is mounted near a viewing port of the chamber and directed to view the surface of the melt 118. The camera 130 produces signals indicative of a camera image on a control line 136 and provides the signals to the control unit 102. The temperature sensor 132 detects temperature in the chamber 106 and provides data indicative of the temperature to the control unit 102 on a control line 138.

The control unit 102 in the illustrated embodiment generally includes a central processing unit (CPU) 140, a memory 142 and a user interface 144. The CPU 140 may be any suitable processing device such as a microprocessor, digital signal processor, digital logic function or a computer. The CPU 140 operates according to data and instructions stored in memory 142. Further, the CPU 140 operates using data and other information received from sensor such as over control lines 126, 128, 136, 138. Still further, the CPU 140 operates to generate control signals to control portions of the semiconductor crystal growth apparatus 100 such as the heater power supply 104, the crystal drive unit 108 and the crucible drive unit 112.

The memory 142 may be any type of dynamic or persistent memory such as semiconductor memory, magnetic or optical disk or any combination of these or other storage. In some applications, the present invention may be embodied as a computer readable storage medium containing data to cause the CPU 140 to perform certain specified functions in conjunction with other components of the semiconductor crystal growth apparatus 100.

The user interface 144 permits user control and monitoring of the semiconductor crystal growth apparatus 100. The user interface 144 may include any suitable display for providing operational information to a user and may include any sort of keyboard or switches to permit user control and actuation of the semiconductor crystal growth apparatus 100.

The semiconductor crystal growth apparatus 100 enables growth of a single crystal semiconductor ingot according to the Czochralski process. According to this process, semiconductor material such as silicon is placed in the crucible 116. The heater power supply 104 actuates the heater 120 to heat the silicon and cause it to melt. The heater 120 maintains the silicon melt 118 in a liquid state. According to the conventional process, a seed crystal 146 is attached to the crystal drive shaft 110. The seed crystal 146 is lowered into the melt 118 by the crystal drive unit 108. Further, the crystal drive unit 108 causes the crystal drive shaft 110 and the seed crystal 146 to rotate in a first direction, such as counterclockwise, while the crucible drive unit 112 causes the crucible drive shaft 114 and the crucible 116 to rotate in the opposite direction, such as clockwise. The crucible drive unit 112 may also raise or lower the crucible 116 as required during the crystal growth process. For example, the melt 118 depletes as the crystal is grown, so the crucible drive unit is raised to compensate and keep the melt level substantially constant. During this process, the heater power supply 104, the crystal drive unit 108 and the crucible drive unit 112 all operate under control of the control unit 102.

For simplifying the following discussion, the heat balance equation, Equation, 1, is normalized:

v=g_{S}−g_{L} (2)

by substitution of.

g_{S}=k_{S}/L G_{S} (3a)

g_{L}=k_{L}/L G_{L} (3b)

Further, the following discussion is based on the following normalized ratios:

r_{S}=v/g_{S} (4a)

r_{L}=v/g_{L} (4b)

From Equation 2, the following statements can be deduced. The following must be true, or else the crystal would melt instead of grow.

g_{S}>g_{L} (5a)

r_{S}<1 (5b)

And one can further derive the following relations between r_{S} and r_{L}

r_{L}=r_{S}/(1−r_{S}) (6a)

r_{S}=r_{L}/(1+r_{L}) (6b)

g_{S}/g_{L}=1/(1−r_{S})=1+r_{L} (6c)

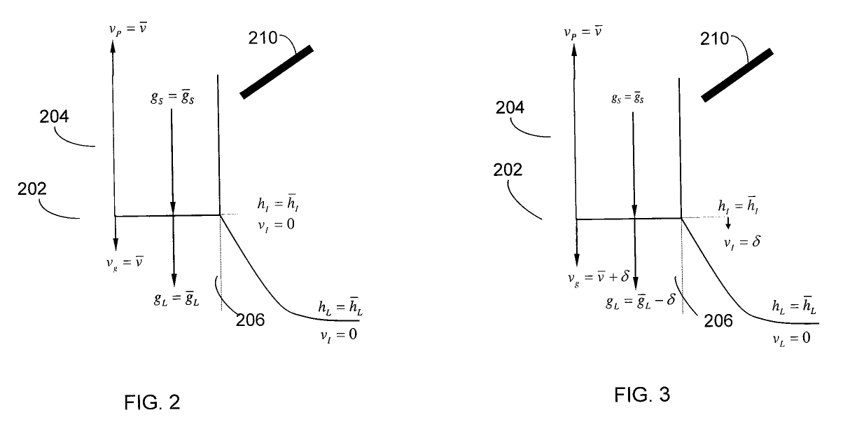

FIG. 2-FIG. 8 are a series of drawings illustrating heat balance in a semiconductor crystal growth apparatus. In each of these figures, the crystal-melt interface 202 is shown along with the crystal 204 and the melt 206. FIG. 2 shows the crystal-melt interface 202 under ideal conditions. FIG. 2 also shows the crystal, 204, the melt 208, and heat reflector 210.

FIG. 2 also shows the nominal crystal-melt interface position, indicated as hₗ= h̅ₗ̅, and zero velocity, indicated as vₗ=0. FIG. 2 further shows the melt position, indicated as h_{L}= h̅_̅{̅L̅}̅ and zero velocity, indicated as v_{L}=0. Still further, FIG. 2 shows the crystal thermal gradient under ideal conditions, or g_{S}= g̅_̅{̅S̅}̅, and the melt thermal gradient under ideal conditions, or g_{L}= g̅_̅{̅L̅}̅. Finally, FIG. 2 shows the growth velocity v_{g}= v̅ and the pull speed v_{P}= v̅.

FIG. 3 shows the crystal-melt interface 202 just after a melt temperature gradient deviation has occurred. In FIG. 3, the crystal-melt interface velocity under this condition is now vₗ=δ, the crystal thermal gradient remains g_{S}= g̅_̅{̅S̅}̅ but the melt thermal gradient has a deviation, or g_{L}= g̅_̅{̅L̅}̅−δ The growth velocity is now v_{g}= v̅+δ. Without operation of a diameter control system, the pull speed remains v_{P}= v̅.

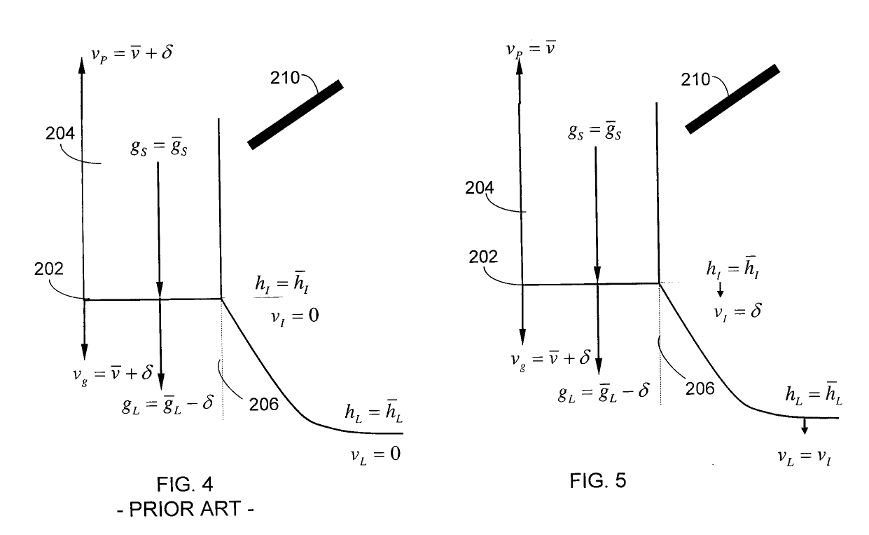

FIG. 4 shows the crystal-melt interface 202 after the conventional diameter control system reacts to the melt temperature gradient deviation illustrated in FIG. 3. It shows the crystal-melt interface velocity has returned to vₗ=0 upon application of the correction. The melt thermal gradient still has a deviation, g_{L}= g̅_̅{̅L̅}̅−δ, as does the growth velocity, v_{g}= v̅+δ. The applied correction is the adjusted pull speed, or v_{P}= v̅+δ.

FIG. 5 shows the crystal-melt interface 202 under operation of a first embodiment of an improved diameter control system. The diameter control system is beginning to react to the melt temperature gradient deviation. FIG. 5 shows the crystal-melt interface velocity is at vₗ=δ. The melt position is still at h_{L}= h̅_̅{̅L̅}̅ but the corrected melt velocity is v_{L}=δ, following the crystal-melt interface. The crystal thermal gradient is still at g_{S}= g̅_̅{̅S̅}̅ and the melt thermal gradient with deviation remains at g_{L}= g̅_̅{̅L̅}̅−δ. The growth velocity is now at v_{g}= v̅+δ and the pull speed is at v_{P}= v̅.

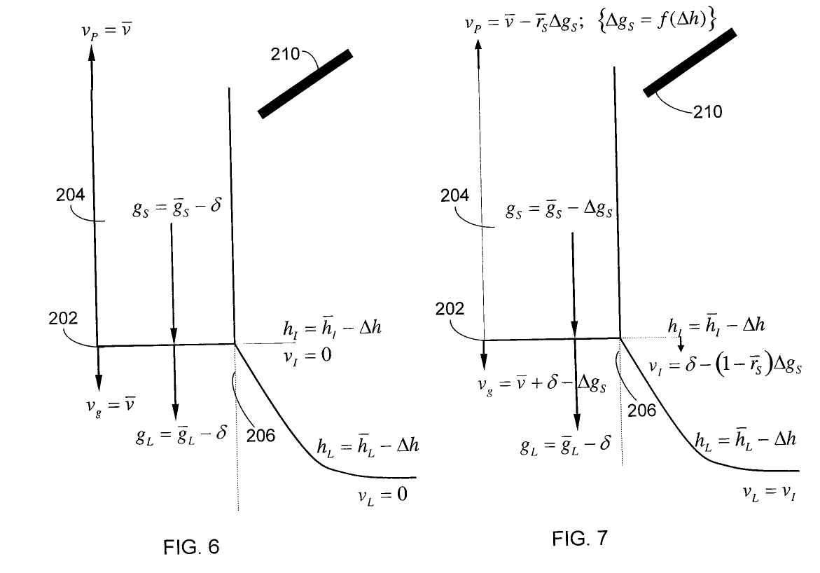

FIG. 6 shows the crystal-melt interface 202 with the first embodiment of the improved diameter control system controlling the melt temperature gradient deviation. FIG. 6 shows the crystal-melt interface position changed to hₗ= h̅ₗ̅−Δh and zero velocity, vₗ=0. FIG. 6 also shows the changed melt position h_{L}= h̅_̅{̅L̅}̅−Δh and zero velocity v_{L}=0. The corrected crystal thermal gradient is now g_{S}= g̅_̅{̅S̅}̅−δ and the melt thermal gradient with deviation is now g_{L}= g̅_̅{̅L̅}̅−δ. The growth velocity and the pull speed are now v_{g}= v̅ and v_{P}= v̅, respectively.

FIG. 7 shows the crystal-melt interface with a second embodiment of an improved diameter control system. In FIG. 7, the improved diameter control system continues to react to a melt temperature gradient deviation, adjusting the pull speed to keep r_{S} constant as the crystal thermal gradient is changing. FIG. 7 shows the crystal-melt interface at a position hₗ= h̅ₗ̅−Δh but the interface position velocity is now at vₗ=δ−(1− r̅_̅{̅S̅}̅)Δg_{S}. The melt position is at h_{L}= h̅_̅{̅L̅}̅−Δh and the corrected velocity is v_{L}=vₗ, following the crystal-melt interface. The crystal thermal gradient is now g_{S}= g̅_̅{̅S̅}̅−Δg_{S}. The melt thermal gradient, with deviation is now g_{L}= g̅_̅{̅L̅}̅−δ. The growth velocity is now v_{g}= v̅+−Δg_{S} and the adjusted pull speed v_{P}= v̅− r̅_̅{̅S̅}̅Δg_{S}, where Δgₛ=f(Δh).

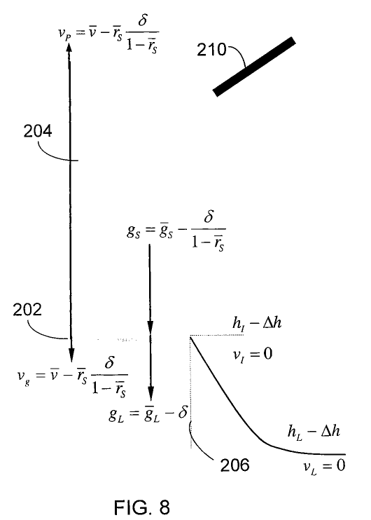

FIG. 8 shows the crystal-melt interface with the second embodiment diameter control system controlling the melt temperature gradient deviation. FIG. 8 shows the crystal-melt interface position at hₗ= h̅ₗ̅−Δh and zero velocity, vₗ=0. FIG. 8 also shows the melt position h_{L}= h̅_̅{̅L̅}̅−Δh and zero velocity v_{L}=0. The corrected crystal thermal gradient is now

$${g}_{S} + \overline{{g}_{S}} - \frac{δ}{1 - \overline{{r}_{s}}} .$$

The melt thermal gradient with deviation is g_{L}= g̅_̅{̅L̅}̅−δ. The growth velocity is

$${v}_{g} = \overline{v} - \overline{{r}_{S}} \frac{δ}{1 - \overline{{r}_{S}}}$$

and the adjusted pull speed is

$${v}_{P} = \overline{v} - \overline{{r}_{S}} \frac{δ}{1 - \overline{{r}_{s}}} .$$

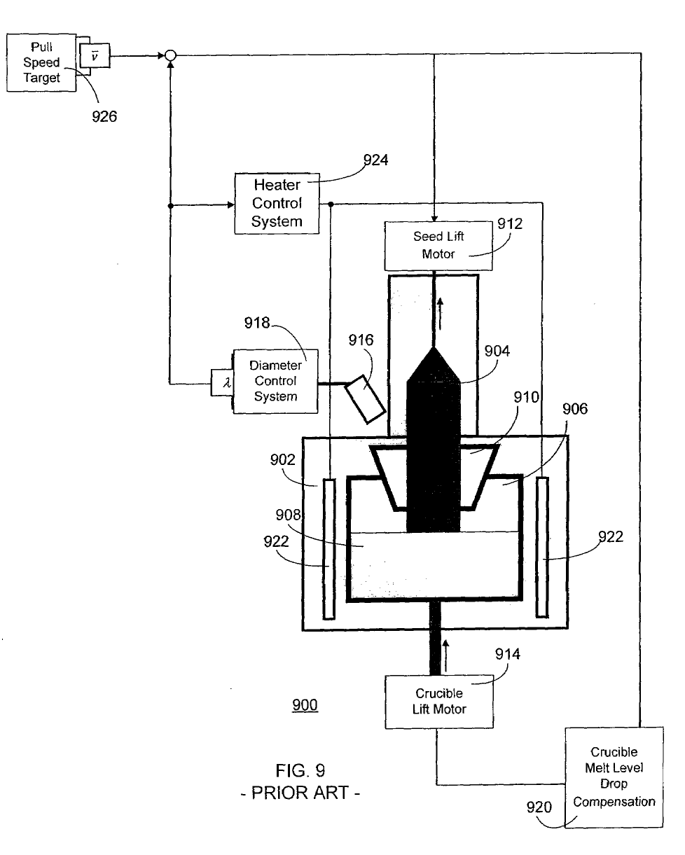

FIG. 9 illustrates a conventional semiconductor crystal growth apparatus 900 implementing prior art diameter control. The apparatus 900 includes a pull chamber 902 including a crystal 904 being pulled from a crucible 906. Melt 908 is contained in the crucible 906. The system 900 further includes a heat reflector 910, a seed lift motor 912 and a crucible lift motor 914. The system 900 further includes a crystal diameter measuring device 916 and an associated diameter control system 918. A crucible melt level drop compensation mechanism 920 controls the crucible lift motor 914. The system 900 further includes a heater 922 and a heater feed-back control system 924, designed to make the average speed correction of the diameter control system zero by adjusting the melt temperature through the supplied heater power.

In general, the crystal growth apparatus 900 includes a control system of the type described above in connection with FIG. 1. The control system produces a target pull speed output 926, generating the nominal pull speed signal for the seed lift motor 912. Similarly, the control system produces a control signal to control the crucible melt level drop compensation mechanism 920, generating a crucible lift with the crucible lift motor 914 designed to compensate the dropping crucible melt level.

For diameter control, the control system of the apparatus 900 includes diameter control system 918. This system generates a pull speed correction signal for the seed lift motor 912. The pull speed correction signal is designed to maintain a constant crystal diameter for the crystal 904.

As the crystal 904 is pulled out of the melt 908, the melt level in the crucible 906 drops. Simultaneously, the crucible 906 is being raised by the crucible lift motor 914 in order to compensate the dropping crucible melt level, such that the melt position and with that the gap between the melt surface and the heat reflector 910 remains constant and with that the thermal gradient gₛ in the crystal 904.

The speed at which the crystal 904 is pulled out of the melt 908 is determined by the target pull speed v̅ plus a corrective term λ coming from the diameter control system 918.

Ideally, the corrective term λ is zero, as is indicated in FIG. 2 and the associated text. However, due to buoyancy fluctuations in the melt flow, the melt temperature gradient at the crystal melt interface too is subject to fluctuations. A melt temperature gradient fluctuation −δ will cause the crystal-melt interface to change at a rate v₁=δ, which is the difference between pull speed and growth rate, as illustrated in FIG. 3. As a result, the wetting angle changes, causing the diameter of the crystal to start changing.

The diameter control system 918, in response to the observed diameter change, then generates a speed correction λ, which is applied to the pull speed to react to the original disturbance just so that the diameter remains constant. Also, the position of the crystal-melt interface remains constant, as illustrated in FIG. 4. The diameter control system 918 implements a closed-loop feed-back-control system. Its output signal will substantially be the signal that keeps the diameter constant, which in the current case is λ=vₗ.

For this conventional diameter control example, the ratios r_{S} and r_{L} can be expressed in terms of average values v̅, g̅_{S}, g̅_{L} and δ as follows (with reference to FIG. 4):

$$\begin{matrix}{r}_{S} = \frac{v}{{g}_{S}} = \frac{\overline{v} + δ}{{\overline{g}}_{S}} \\ and & ( 7 ) \\ {r}_{L} = \frac{v}{{g}_{L}} = \frac{\overline{v} + δ}{{\overline{g}}_{L} - δ} & ( 8 )\end{matrix}$$

Following from that, the deviations of these ratios that are caused by buoyancy-driven melt temperature gradient fluctuations δ and the control system reacting to it can be estimated as follows.

$$\begin{matrix}Δ {r}_{S} = \frac{δ}{{\overline{g}}_{S}} \\ and & ( 9 ) \\ Δ {r}_{L} = ( 1 + {\overline{r}}_{L} ) \frac{δ}{{\overline{g}}_{L}} & ( 10 )\end{matrix}$$

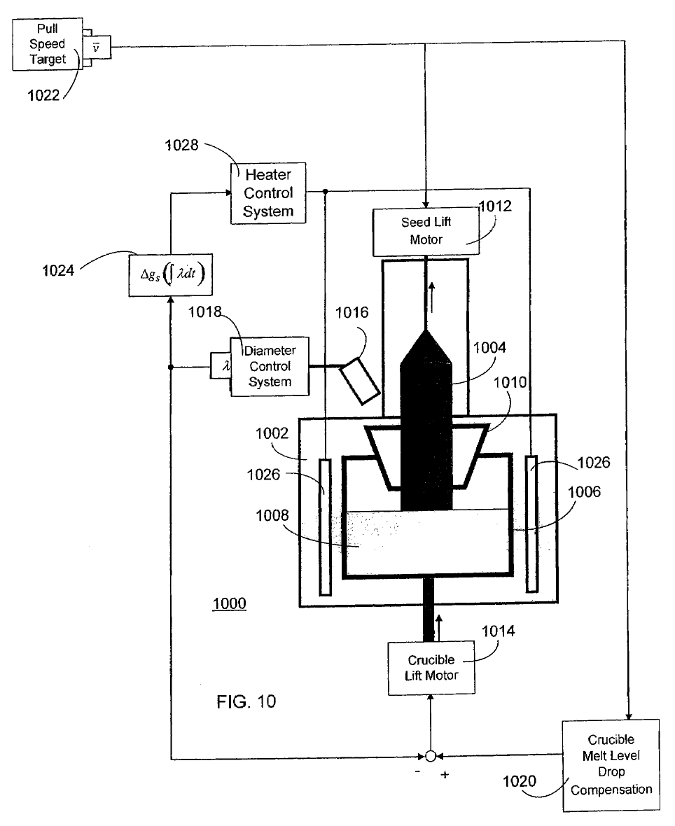

FIG. 10 illustrates a first embodiment of diameter control in a semiconductor crystal growth apparatus 1000. The apparatus 1000 includes a pull chamber 1002 including a crystal 1004 being pulled from a crucible 1006. Melt 1008 is contained in the crucible 1006. The system 1000 further includes a heat reflector 1010, a seed lift motor 1012 and a crucible lift motor 1014. The system 1000 further includes a crystal diameter measuring device 1016 and an associated diameter control system 1018. A crucible melt level drop compensation mechanism 1020 controls the crucible lift motor 1014. A control system target pull speed output 1022 is a portion of a control system such as the control system 102 of FIG. 1. The system 1000 further includes a device 1024 that estimates the gradient change Δg_{S}, which is a result of a melt-position change, which is the result of the diameter control system supplying a corrective term to the crucible lift. The system 1000 further includes a heater 1026 and a heater feed-back control system 1028, designed to make the average gradient adjustment Δg_{S} zero by adjusting the melt temperature through the supplied heater power.

The control system's target pull speed output 1022 generates the nominal pull speed signal for the seed lift motor 1012. The control system crucible melt level drop compensation mechanism 1020 generates a crucible lift signal to be applied to the crucible lift motor 1014 to compensate the dropping crucible melt level. The control system diameter control system 1018 generates a pull speed correction designed to maintain a constant crystal diameter.

The crystal 1004 is pulled out of the melt 1008 at a predetermined pull speed v̅. Simultaneously, the crucible 1006 is being raised by the crucible lift motor 1014 at a speed that is a combination of a speed that compensates the melt level drop in the crucible 1006 that is caused by pulling the crystal at speed v̅, minus the corrective term λ that is the output of the diameter control system 1018.

Ideally, the corrective term is zero, as illustrated in conjunction with FIG. 2. However, when, as a result of a buoyancy fluctuation in the melt flow, a melt temperature gradient fluctuation −δ occurs, the crystal melt interface begins to change at a rate vₗ=δ (see FIG. 3). The resulting change in meniscus height and wetting angle eventually causes a diameter change, which is detected by the diameter control system 1018. The diameter control system 1018 then generates an output term λ which is subtracted from the crucible lift. Since the diameter control system 1018 is part of a closed-loop feedback-control-system, the diameter control output signal will make the melt position follow the crystal-melt interface at the same rate v_{L}=vₗ=δ (see FIG. 5), keeping meniscus height, wetting angle and the diameter constant.

The result is a widening gap between the heat reflector 1010 and melt-surface. This in turn causes the thermal gradient in the crystal 1004 to change. As a result, eventually the crystal-melt interface will stop changing once the thermal gradient in the crystal has changed to be g_{S}= g̅_{S}−δ, because then the heat balance equation results in a growth rate that is equal to the pull rate v_{P}=v_{g}=g_{S}−g_{L}= v̅ (see FIG. 6). At that point, the output signal of the diameter control system 1018 will become zero, because it will no longer detect a diameter change.

In such system, the ratios r_{S} and r_{L}, expressed in terms of average values v̅, g̅_{S}, g̅_{L} and δ, will become.

$${r}_{S} = \frac{v}{{g}_{S}} = \frac{\overline{v}}{{\overline{g}}_{S} - δ}$$

$$and$$

$${r}_{L} = \frac{v}{{g}_{L}} = \frac{\overline{v}}{{\overline{g}}_{L} - δ}$$

and the resulting deviations of these ratios from their ideal values can be estimated as follows.

$$Δ {r}_{S} = {\overline{r}}_{S} \frac{δ}{{\overline{g}}_{S}}$$

$$and$$

$$Δ {r}_{L} = {\overline{r}}_{L} \frac{δ}{{\overline{g}}_{L}}$$

Since r̅_{S} is always smaller than 1, this method will always reduce r_{S} variations compared to conventional systems.

In the case of low defect silicon production, where smallest possible r̅_{S} variation has highest priority, r̅_{S} is typically in the neighborhood of 0.5. This means that in such a case the improved system and method described herein will provide the same diameter control performance at 50% less r_{S} variations compared to prior art.

The improved control system and method reduces r_{L} variations by a factor

$$\frac{{\overline{r}}_{L}}{1 + {\overline{r}}_{L}}$$

compared to conventional diameter control systems. In the case of heavily doped silicon production, where smallest possible r̅_{L} and smallest possible r_{L} variation is most important, r̅_{L}is typically smaller than 1. In such case, the improved control apparatus and method will provide the same diameter control performance with more than 50% smaller r_{L} variations compared to conventional systems.

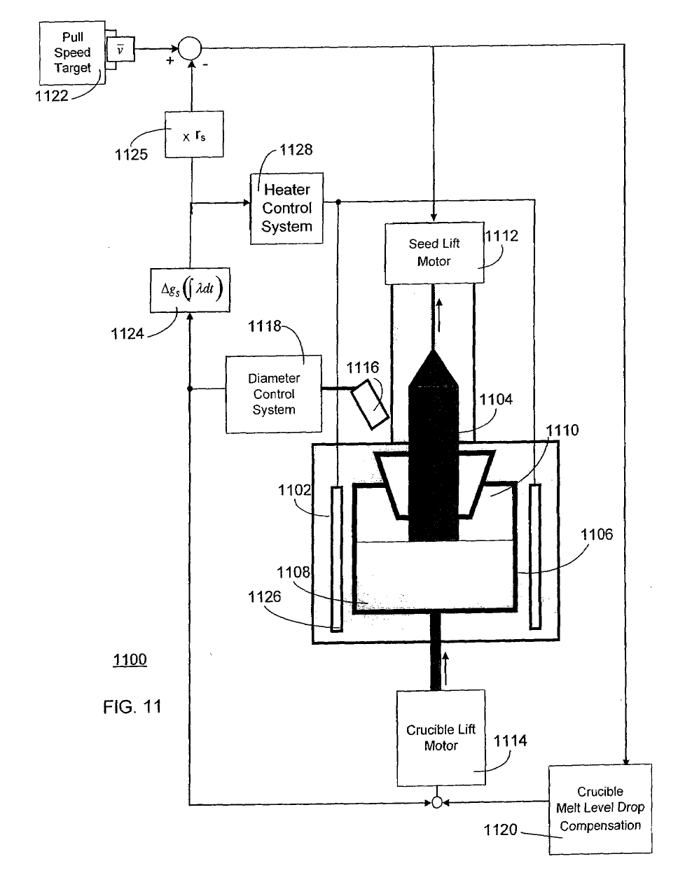

FIG. 11 illustrates a second prior art diameter control in a semiconductor crystal growth system 1100. The system 1100 includes a pull chamber 1102 including a crystal 1104 being pulled from a crucible 1106. Melt 1108 is contained in the crucible 1106. The system 1100 further includes a heat reflector 1110, a seed lift motor 1112 and a crucible lift motor 1114. The system 1100 further includes a crystal diameter measuring device 1116 and an associated diameter control system 1118. A crucible melt level drop compensation mechanism 1120 controls the crucible lift motor 1114.

FIG. 11 illustrates a second embodiment of diameter control in a semiconductor crystal growth apparatus 1100. The apparatus 1100 includes a pull chamber 1102 including a crystal 1104 being pulled from a crucible 1106. Melt 1108 is contained in the crucible 1106. The system 1100 further includes a heat reflector 1110, a seed lift motor 1112 and a crucible lift motor 1114. The system 1100 further includes a crystal diameter measuring device 1116 and an associated diameter control system 1118. A crucible melt level drop compensation mechanism 1120 controls the crucible lift motor 1114. A control system target pull speed output 1122 is a portion of a control system such as the control system 102 of FIG. 1. The system 1100 further includes a device 1124 that estimates the gradient change Δg_{S}, which is a result of a melt-position change, which is the result of the diameter control system supplying a corrective term to the crucible lift. The system 1100 also includes a v/G correction component 1125. The system 1100 further includes a heater 1126 and a heater feed-back control system 1128, designed to make the average gradient adjustment Δg_{S} zero by adjusting the melt temperature through the supplied heater power.

In operation, the control system target pull speed output 1122 generates the nominal pull speed signal for the seed lift motor 1112. The crucible melt level drop compensation system 1120 generates a crucible lift signal to compensate the dropping crucible melt level as the crystal 1104 is pulled from the crucible 1106. The diameter control 1118 generates a pull speed correction signal designed to maintain a constant crystal diameter. The v/G correction component 1125, according to the gradient change estimated in the device 1124, generates a speed correction term to modify v with the changing crystal temperature gradient, in order to keep r_{S}=v/g_{S} exactly at the desired value of r̅_{S}= v̅/ g̅_{S}. The correction term is combined with the nominal pull speed signal.

As in the system 1000 illustrated in FIG. 10, the crystal 1104 is pulled out of the melt 1108 and simultaneously the crucible 1106 is raised by the crucible lift motor 1114 at a speed that is a combination of a speed that compensates the melt level drop in the crucible 1106 that is caused by pulling the crystal 1104, minus the corrective term λ that is the output of the diameter control system 1118.

In contrast to the system 1000 illustrated in FIG. 10, the pull speed in the system 1100 of FIG. 11 includes the predetermined speed v̅ plus a corrective term. This corrective term is derived from the change in melt position (the integral over the diameter control system output that was applied to the crucible lift), which is used to estimate the change in crystal temperature gradient that is the result of the melt position change. For small melt position changes, the change in crystal temperature gradient is nearly proportional to the melt position change and the relation between the two can be estimated from computer simulations.

Again, as in system 1000 illustrated in FIG. 10, starting with the undisturbed state (see FIG. 2), a melt temperature gradient fluctuation −δ causes the crystal melt interface to change at a rate vₗ=δ (see FIG. 3). This resulting change in diameter is detected by the diameter control system 1118, which generates an output term λ, which is subtracted from the crucible lift signal. Being a closed-loop feed-back-control that keeps the diameter constant, the diameter control's output λ is going to be a value that causes the melt position to follow the crystal-melt interface at the rate λ=v_{L}=vₗ (see FIG. 4), keeping the wetting angle, and with it the diameter, constant (see FIG. 4).

As the melt position changes, the change in crystal temperature gradient Δg_{S} is estimated based on the accumulated melt position changes Δh. The pull-speed is corrected by the term r̅_{S}·Δg_{S}, so that the actual ratio r_{S} remains constant at

$${r}_{S} = \frac{\overline{v} + {\overline{r}}_{S} \cdot Δ {g}_{S}}{{\overline{g}}_{S} + Δ {g}_{S}} = {\overline{r}}_{S}$$

### (see FIG. 6).

As in the system 1000 illustrated in FIG. 10, the result is a widening gap between the heat reflector 1110 and the melt-surface, which causes the thermal gradient in the crystal 1104 to change. The crystal-melt interface will stop changing once the thermal gradient in the crystal 1104 has changed enough such that the pull speed and growth rate are equal v_{P}=v_{g}.

However, in contrast to system 1000 of FIG. 10, in the system 1100 of FIG. 11, that will happen now when

$${g}_{S} = {\overline{g}}_{S} - \frac{δ}{1 - {\overline{r}}_{S}}$$

and

$${v}_{p} = {v}_{g} = \overline{v} - {\overline{r}}_{S} \frac{δ}{1 - {\overline{r}}_{S}} ,$$

because the pull speed is adjusted for the changing crystal temperature gradient.

In the controlled state, with active diameter control, the ratios r_{S} and r_{L} can be expressed in terms of average values v̅, g̅_{S}, g̅_{L} and δ.

$${r}_{S} = \frac{v}{{g}_{S}} = \frac{\overline{v} - {\overline{r}}_{S} \frac{δ}{1 - {\overline{r}}_{S}}}{{\overline{g}}_{S} - \frac{δ}{1 - {\overline{r}}_{S}}}$$

$$and$$

$${r}_{L} = \frac{v}{{g}_{L}} = \frac{\overline{v} - {\overline{r}}_{S} \frac{δ}{1 - {\overline{r}}_{S}}}{{\overline{g}}_{L} - δ}$$

Following from that, the r_{S} deviation, by design, is now zero

$$Δ {r}_{S} = 0 = ( \frac{\overline{v}}{{\overline{g}}_{S}} \frac{1}{1 - {\overline{r}}_{S}} - \frac{{\overline{r}}_{S}}{1 - {\overline{r}}_{S}} ) \frac{δ}{{\overline{g}}_{S}}$$

and the r_{L} deviation will be

$$Δ {r}_{L} = \frac{\overline{v}}{{\overline{g}}_{L}} \frac{δ}{{\overline{g}}_{L}} - \frac{{\overline{r}}_{S}}{1 - {\overline{r}}_{S}} \frac{δ}{{\overline{g}}_{L}}$$

which, by using Equations (4b) and (6a) above also turns out to be zero.

$$Δ {r}_{L} = 0 = {\overline{r}}_{L} \frac{δ}{{\overline{g}}_{L}} - {\overline{r}}_{L} \frac{δ}{{\overline{g}}_{L}}$$

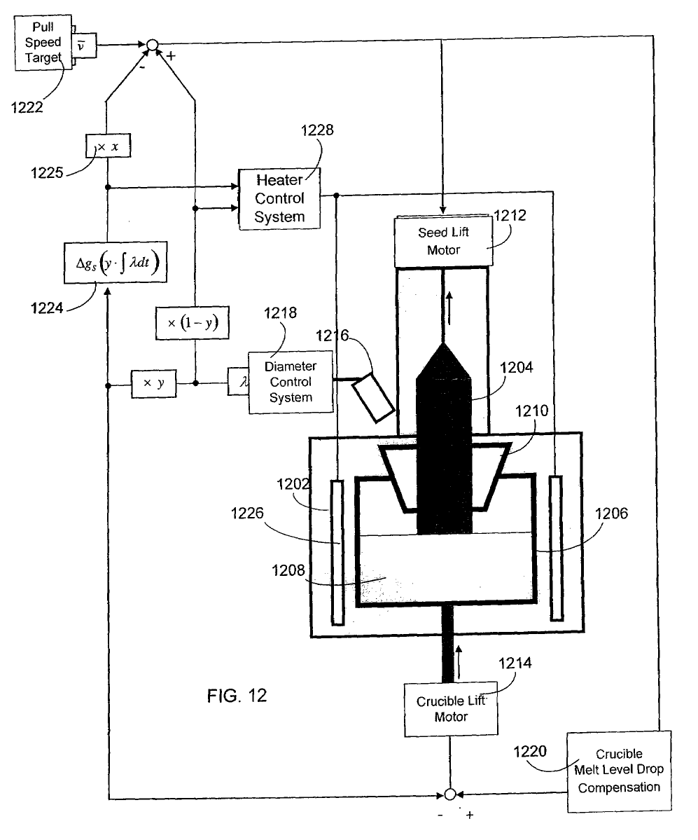

FIG. 12 illustrates a third prior art diameter control in a semiconductor crystal growth system 1200. The system 1200 includes a pull chamber 1202 including a crystal 1204 being pulled from a crucible 1206. Melt 1208 is contained in the crucible 1206. The system 1200 further includes a heat reflector 1210, a seed lift motor 1212 and a crucible lift motor 1214. The system 1200 further includes a crystal diameter measuring device 1216 and an associated diameter control system 1218. A crucible melt level drop compensation mechanism 1220 controls the crucible lift motor 1214.

The system 1200 includes a control system similar to the control system 102 of FIG. 1. The control system has a target pull speed output 1222 which generates a nominal pull speed signal for the seed lift motor 1212. The control system further includes a crucible melt level drop compensation mechanism 1220 which generates a crucible lift signal to compensate the dropping crucible melt level. The control system also includes a diameter control mechanism 1218 which generates a pull speed correction signal designed to maintain a constant crystal diameter.

The system 1200 further includes a device 1224 that estimates the gradient change Δg_{S}, which is a result of a melt-position change. The control system further includes a v/G correction system 1225. The v/G correction system 1225 of the control system operates according to a parameter x which determines a combination between the first embodiment described above in conjunction with FIG. 10 and the second embodiment described above in conjunction with FIG. 11. The control system responds to the value of the parameter x and generates a speed correction term with the changing crystal temperature gradient multiplied by the parameter x. Further, a parameter y determines a combination between traditional control and control in accordance with the embodiments described herein.

From the foregoing, it can be seen that the present invention provides an improved method and system for controlling growth of a semiconductor crystal. The embodiments disclosed herein provide reliable control of the diameter of the crystal. In addition, these embodiments also reduce the effect of factors such as buoyancy in the melt on temperature gradients in the melt and in the crystal. The important parameter v/G is precisely controlled.

It is therefore intended that the foregoing detailed description be regarded as illustrative rather than limiting, and that it be understood that it is the following claims, including all equivalents, that are intended to define the spirit and scope of this invention.

1. A semiconductor crystal growth method comprising:
pulling a crystal from melt in a crucible at a nominal pull speed;
generating a crucible lift signal to compensate reduction in melt level in the crucible;
based on diameter of the crystal, generating a correction signal; and
combining the crucible lift signal and the correction signal to keep the diameter substantially constant.

2. The semiconductor crystal growth method of claim 1 further comprising:
lifting the crucible in response to the crucible lift signal to compensate reduction in melt level in the crucible.

3. The semiconductor crystal growth method of claim 1 further comprising:
detecting variation in the diameter of the crystal due to buoyancy fluctuation in the melt.

4. The semiconductor crystal growth method of claim 1 further comprising:
detecting variation in the diameter of the crystal due to variation in position of an interface between the crystal and the melt.

5. The semiconductor crystal growth method of claim 4 wherein generating a correction signal comprises:
generating a correction signal to make the position of the melt follow the position of the interface between the crystal and the melt.

6. A crystal manufacturing apparatus comprising:
a crucible to hold melt;
a seed lift motor to pull a crystal from the melt in response to a speed signal;
a crucible lift motor to lift the crucible in response to a lift signal;
a control system including
a crucible melt level drop compensation module to generate the lift signal to compensate reduction in melt level in the crucible due to pulling the crystal from the melt, and
a diameter control module to generate a correction signal, wherein
the crucible lift motor is responsive to the lift signal and the pull speed correction signal to maintain a substantially constant crystal diameter.

7. The crystal manufacturing apparatus of claim 6 further comprising:
a combiner to combine the lift signal and the pull speed correction signal and to generate a lift motor control signal.

8. The crystal manufacturing apparatus of claim 6 further comprising:
a crystal diameter measuring system to detect variations in the diameter of the crystal and produce a diameter signal, the diameter control module responsive to the diameter signal to generate the pull speed correction signal.

9. The crystal manufacturing apparatus of claim 8 wherein the crystal diameter measuring system is configured to detect diameter variations due to buoyancy fluctuation in the melt.

10. The crystal manufacturing apparatus of claim 8 wherein the crystal diameter measuring system is configured to detect diameter variations due to variation of a crystal-melt interface in the crucible.

11. The crystal manufacturing apparatus of claim 8 wherein the crystal diameter measuring system is configured to detect diameter variations due to temperature gradient variation in the melt.

12. The crystal manufacturing apparatus of claim 6 wherein the control system further comprises:
a target speed module to generate a nominal pull speed signal for the seed lift motor,

13. A semiconductor crystal growth method comprising:
pulling a crystal from melt in a crucible at a nominal pull speed;
generating a pull speed correction based on an estimate of the change in crystal temperature gradient that results from melt position change in the crucible;
combining the nominal pull speed and the pull speed correction to produce an adjusted pull speed for pulling the crystal from the melt in the crucible;
generating a crucible lift signal to compensate reduction in melt level in the crucible;
based on diameter of the crystal, generating a lift correction signal; and
combining the crucible lift signal and the lift correction signal to keep the diameter substantially constant.

14. The method of claim 13 wherein generating a pull speed correction comprises generating a pull speed correction based on a change in melt position in the crucible.

15. The method of claim 13 wherein the pull speed correction is generated using the lift correction signal.

16. The method of claim 13 further comprising:
detecting variations in the diameter of the crystal;
based on the variations in the diameter, generating the pull speed correction; and
based on the variations in the diameter, generating the lift correction signal.

17. The semiconductor crystal growth method of claim 16 wherein detecting variations in the diameter of the crystal comprises:
detecting variations in the diameter of the crystal due to buoyancy fluctuation in the melt.

18. The semiconductor crystal growth method of claim 13 further comprising:
lifting the crucible in response to the crucible lift signal to compensate reduction in melt level in the crucible.

19. A crystal manufacturing apparatus comprising:
a crucible to hold melt;
a seed lift motor to pull a crystal from the melt in response to a speed signal;
a crucible lift motor to lift the crucible in response to a lift signal;
a control system including
a target speed module to generate a nominal speed signal,
a pull speed correction module to generate a pull speed correction signal in response to changing crystal temperature gradient,
a crucible melt level drop compensation module to generate the lift signal to compensate reduction in melt level in the crucible due to pulling the crystal from the melt, and
a diameter control module to generate a correction signal, wherein
the crucible lift motor is responsive to the lift signal and the pull speed correction signal to maintain a substantially constant crystal diameter.

20. The crystal manufacturing apparatus of claim 19 wherein the pull speed correction module is responsive to the correction signal from the diameter control module to generate the pull speed correction signal and wherein the crucible melt level drop compensation module is responsive to the correction signal to generate the lift signal.
